(19) United States
(12) Patent Application Publication
(10) Pub. No.: US 2007/0063754 A1
(43) Pub. Date: Mar. 22, 2007

(54) Frequency generator

(76) Inventor: Duyen Pham-Stabner, Ratingen (DE)

Correspondence Address: ESCHWEILER & ASSOCIATES, LLC;NATIONAL CITY BANK BUILDING, 629 EUCLID AVE., SUITE 1000, CLEVELAND, OH, 44114, US

(21) Appl. No.: 11/416,216

(22) Filed: May 2, 2006

Related U.S. Application Data
(63) Continuation of application No. PCT/DE04/02200, filed on Oct. 1, 2004.

(30) Foreign Application Priority Data
Nov. 3, 2003 (DE) DE 10351116.4

(51) Int. Cl. H03H 11/26

(52) U.S. Cl. 327/261; 379/361

(57) ABSTRACT

A frequency generator is specified which includes a pulse generator with a downstream signal conditioning circuit. The pulse generator is designed for recurring emission of pulses. The signal conditioning circuit derives a signal at a desired frequency from higher harmonic frequency components of the electrical pulses. The circuit makes it possible to produce a radio-frequency signal from a low-frequency clock signal, with little complexity and a small chip area. This is suitable, for example, for mixing with a further signal frequency onto a carrier frequency or an intermediate frequency in transceivers.

### REFERENCE TO RELATED APPLICATIONS

This application is a continuation of PCT/DE2004/002200 filed Oct. 1, 2004 which was not published in English, that claims the benefit of the priority date of German Patent Application No. DE 103 51 116.4, filed on Nov. 3, 2003, the contents of which both are herein incorporated by reference in their entireties.

### FIELD OF THE INVENTION

The present invention relates to a frequency generator, for example, for production of radio-frequency carrier signals in the Gigahertz range.

### BACKGROUND OF THE INVENTION

In transceivers, that is to say transceivers for information technology, in particular for mobile radio, intermediate-frequency and radio-frequency signals are normally produced by using a frequency mixer to combine two input signals at different frequencies. The two input signals to the frequency mixer are normally produced by oscillators. The oscillators which are often used in this case are those with a tunable frequency, and which are normally in the form of integrated voltage controlled oscillators, VCO.

Oscillators such as these have to satisfy stringent requirements and are complex to implement using integrated circuit technology. Furthermore, the oscillators occupy a relatively large area. LC tuned circuits are normally used as resonant circuits, requiring relatively large-area integrated coils.

The document JP 01-039113 A specifies a circuit for production of pulses with a variable pulse width. A capacitor is provided, by means of which a time delay is achieved. An input signal and the delayed signal are linked to one another in a logic AND gate. The integration of the capacitance in semiconductor circuit technology occupies a relatively large area and, in addition, is subject to manufacturing tolerances.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present one or more concepts of the invention in a simplified form as a prelude to the more detailed description that is presented later.

The invention is directed to a frequency generator which is suitable for the production of signals at radio frequencies, even in the GHz range.

According to one embodiment of the invention, a frequency generator is provided and comprises a pulse generator configured to emit electrical pulses at an output thereof. The frequency generator also comprises a signal conditioning circuit with an input which is connected to the output of the pulse generator. The signal conditioning circuit is configured to emit a signal at a frequency which is derived from higher harmonic frequency components of the electrical pulses.

According to one embodiment of the invention, the pulse generator produces electrical pulses. During this process radio-frequency spectrum components are produced, which are also referred to as harmonics. The signal conditioning circuit is configured to emit a signal at a frequency or in a frequency range which is derived from these higher harmonic frequency components of the recurring electrical pulses from the pulse generator. The signal conditioning circuit is, in one example, connected downstream from the pulse generator.

In one embodiment, the invention advantageously makes it possible to produce harmonics or very-high-order frequency components, even in the Gigahertz frequency range.

The frequency generator according to one embodiment of the invention can be used to replace conventional oscillators which require integrated capacitors and/or integrated inductances. This makes it possible to save a significant amount of chip area.

In one example, the frequency generator is used to produce intermediate frequencies or carrier frequencies which can advantageously be used in transceivers for mobile radio.

The pulse generator, in one example, is configured to provide a programmable pulse width.

The pulse generator, in another example, is configured to produce a signal with a programmable duty ratio.

The pulse generator, in yet another example, is configured to emit a discrete-value signal such as a binary-coded digital signal.

In one embodiment, a periodic clock signal is supplied at the input of the pulse generator and is provided by a clock generator.

In one embodiment the clock generator produces a periodic square-wave signal. The square-wave signal is, in one example, produced by the clock generator in such a way that high and low level durations are each of equal length.

The pulse generator, in one embodiment, is configured such that the duty ratio of the periodic clock signal on the input side can be varied and/or programmed as a function of the control signal.

The spectrum behavior at the output of the pulse generator, in one example, can be influenced by variation of the pulse width and/or of the duty ratio of the output signal from the pulse generator. This makes it possible to influence the frequency of the signal which is emitted from the signal conditioning circuit, thereby allowing the frequency generator to be tunable.

Alternatively or additionally, the frequency generator is tuned by the capability to vary and/or program the gradient of the flanks of the electrical pulses which are emitted from the pulse generator.

The signal conditioning circuit, in one example, includes a signal filtering circuit. For example, high-pass filters or bandpass filters are employed in order to filter the desired frequencies out of the spectrum of the higher harmonics.

Alternatively or additionally, the signal conditioning circuit comprises a signal amplification circuit, in order to produce at the output of the signal conditioning circuit those frequency components which are desired in the spectrum of the output signal from the pulse generator.

In one embodiment the pulse generator comprises a phase detector that is configured to emit pulse-width-modulated signals.

Alternatively or additionally, it is possible to make use of the characteristic of phase detectors that a so-called anti-backlash pulse is produced at the output of the phase detector when two input signals with a matching phase angle are applied. This anti-backlash pulse is also referred to as a dead-time zone. The pulse width and/or the duty ratio of the anti-backlash pulse can be programmed and/or reduced further without any problems by the phase detector having an appropriate programming input.

The invention, in one example, makes it possible to dispense completely with analog, discrete components. In fact, the proposed frequency generator can be produced exclusively from digital components and functional blocks. On the one hand, this results in the advantage that it results in a particularly small area being required for the frequency generator when implemented using integrated circuit technology.

As an additional advantage, the lack of capacitances and/or inductances, in one example, means that the influences of technical-process fluctuations or fluctuations in the manufacturing parameters have considerably less influence on the characteristics of the frequency generator.

The invention, in one embodiment, is used to produce intermediate frequencies, carrier frequencies or local-oscillator frequencies in transceivers for telecommunication purposes. In this example, the frequency generator is connected to the input of a frequency mixer, which mixes the signal frequency produced by the frequency generator with a further frequency and in this way produces the desired intermediate frequency or carrier frequency.

To the accomplishment of the foregoing and related ends, the invention comprises the features hereinafter fully described and particularly pointed out in the claims. The following description and the annexed drawings set forth in detail certain illustrative aspects and implementations of the invention. These are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

The invention will be explained in more detail in the following text using one exemplary embodiment and with reference to the drawings, in which:

FIG. 1 is a block diagram illustrating one embodiment of a frequency generator according to the invention, and

FIG. 2 is a graph illustrating an example of a frequency spectrum of a square-wave pulse.

### DETAILED DESCRIPTION OF THE INVENTION

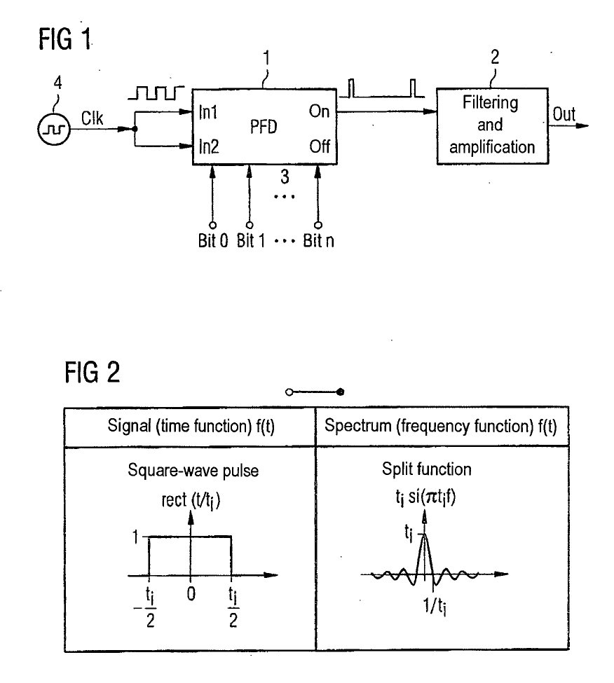

FIG. 1 shows a frequency generator with a pulse generator 1 and a signal conditioning circuit 2, which is connected downstream from the pulse generator 1. The pulse generator 1 emits recurring electrical pulses at an output. The output of the pulse generator is connected to one input of the signal conditioning circuit 2. A signal is produced at the output of the signal conditioning circuit at a frequency which, by virtue of the design of the signal conditioning circuit, is derived from higher harmonic frequency components of the electrical pulses from the pulse generator.

The pulse generator 1 has a programming input 3 which, in one example, is in the form of a digital programming input. The input 3 is designed to supply a programming word whose word length is n. The programming input 3 thus interacts with the pulse generator 1 such that the pulse width of the emitted pulses at the output of the pulse generator 1 can be programmed.

Furthermore, the pulse generator 1, which in one example comprises a phase/frequency detector, has two inputs IN1, IN2. Both inputs IN1, IN2 of the pulse generator 1 are connected to a clock generator 4 for supplying two in-phase input signals. The clock generator 4 is configured to produce a periodic clock signal CLK. The clock signal is a square-wave signal. The clock generator 4 is in the form of a crystal oscillator, in one example. A crystal oscillator such as this is often provided as a system clock transmitter in integrated circuits.

The signal conditioning circuit 2 comprises a filtering circuit and an amplification circuit on the input side, and emits the filtered and amplified signal at its output OUT.

In one embodiment of the invention, the frequency of the system clock CLK is in the MHz range. The system clock CLK in one example is a square-wave signal with a duty ratio of 1:1. This means that the ratio of the duration of the high level to the duration of the low level is 1:1, that is to say they are identical. The pulse generator 1 uses this low-frequency input clock to emit a signal whose duty ratio is considerably less and, for example, is 0.03:1. Compared to the total signal period, the pulse width is accordingly very short. The duty ratio of the pulse, in one embodiment, is programmable at the programming input 3. The frequency spectrum of the signal is influenced by the significant reduction in the pulse width. Frequency notches and, resulting from them, radio-frequency bands are produced as a function of the duty ratio and thus of the pulse width. This characteristic simplifies the filtering process and the subsequent amplification of the desired frequency range.

Consequently the signal tapped off at the output of the signal conditioning circuit 2 can be used readily for frequency mixing according to one embodiment of the invention.

In another embodiment the phase/frequency detector 1 produces pulses at its two outputs ON, OFF, whose pulse width depends on the phase angle of and the frequency difference between the input signals at the inputs IN1, IN2. In the present example, in which the two inputs are always at the same phase angle and frequency, or the phase error is at least less than the dead time of the detector, the pulse generator 1 produces pulses with a constant pulse width, so-called anti-backlash pulses. These pulses are much shorter than the pulse duration at the input. In addition, provision is made in the present example for the capability to vary the pulse duration of the anti-backlash pulses by programming using the programming input 3. This makes it possible to vary the output frequency of the frequency generator.

Accordingly, the actually undesired, higher harmonic frequency components of a pulsed signal are used in order to deliberately extract desired frequencies from the radio-frequency spectrum.

Since both the phase/frequency detector 1 and the filtering and amplification in the signal conditioning circuit 2 can be implemented exclusively with digital components using digital circuit technology, the frequency generator of the invention can be integrated with a particularly small area requirement. Since no analog, discrete components such as capacitances or inductances are required, this also reduces the influence of manufacturing fluctuations as well as temperature fluctuations on the circuit, in particular on the frequency of the output signal.

The present frequency generator, which can also be referred to as a harmonic generator, is particularly suitable as a replacement for oscillators, preferably for radio-frequency oscillators such as LC-VCOs.

FIG. 2 shows a square-wave pulse in the time domain with an associated illustration of the pulse in the frequency domain. The relationship is provided by a Fourier transformation. As can be seen, the associated frequency spectrum can be influenced deliberately by variation of the pulse width tᵢ. In particular, the higher harmonics can be shifted into bands at a greater frequency by reducing the pulse width tᵢ.

Although the invention has been illustrated and described with respect to a certain aspect or various aspects, it is obvious that equivalent alterations and modifications will occur to others skilled in the art upon the reading and understanding of this specification and the annexed drawings. In particular regard to the various functions performed by the above described components (e.g., assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several aspects of the invention, such feature may be combined with one or more other features of the other aspects as may be desired and advantageous for any given or particular application. Furthermore, to the extent that the term “includes” is used in either the detailed description or the claims, such term is intended to be inclusive in a manner similar to the term “comprising.” Also, exemplary is merely intended to mean an example, rather than the best.

1. A frequency generator, comprising:
a pulse generator configured to emit recurring electrical pulses at an output thereof; and
a signal conditioning circuit comprising an input coupled to the output of the pulse generator, and configured to emit a signal at a frequency which is derived from higher harmonic frequency components of the electrical pulses,
wherein the pulse generator comprises a phase detector.

2. The frequency generator of claim 1, wherein the pulse generator comprises a control input, and wherein the pulse generator is configured to emit the pulses as a discrete-value signal with a programmable pulse width as a function of a signal applied to the control input.

3. The frequency generator of claim 1, further comprising a clock generator configured to produce a periodic clock signal and couple the periodic clock signal to one input of the pulse generator.

4. The frequency generator of claim 1, wherein the signal conditioning circuit comprises a signal filtering circuit.

5. The frequency generator of claim 1, wherein the signal conditioning circuit comprises a signal amplification circuit.

6. The frequency generator of claim 1, wherein the phase detector has two inputs configured to receive two input signals having a matching phase angle.

7. The frequency generator of claim 6, further comprising a clock generator configured to produce a periodic clock signal and couple the periodic clock signal to one input of the pulse generator, wherein both inputs of the phase detector are connected to the clock generator.

8. The frequency generator of claim 1, wherein the phase detector comprises a programming input configured to receive a programming signal, and configured to program the duty ratio of the signal at the output of the phase detector based thereon.

9. A frequency generator, comprising:
a pulse generator configured to generate a plurality of signal pulses at an output thereof; and
a signal conditioning circuit configured to receive the plurality of signal pulses and generate an output signal comprising a frequency that is a function of harmonic frequency components associated with the pulses.

10. The frequency generator of claim 9, wherein the signal conditioning circuit comprises a transformation component configured to generate a frequency spectrum response associated with the pulses.

11. The frequency generator of claim 10, wherein the signal conditioning circuit further comprises a filter configured to remove undesired harmonic frequency components of the frequency spectrum response.

12. The frequency generator of claim 9, wherein the pulse generator further comprises a programming input configured to receive a programming signal, wherein a duty cycle of the plurality of pulses is a function of the programming signal.

13. The frequency generator of claim 12, wherein the programming signal comprises a multi-bit digital word.

14. The frequency generator of claim 9, wherein the pulse generator comprises a phase detector circuit comprising first and second inputs, and configured to generate the pulses as a function of a phase angle between signals at the first and second inputs, a frequency difference between signals at the first and second inputs, or both.

15. The frequency generator of claim 14, further comprising a clock generator circuit configured to generate a clock signal connected to the first and second inputs of the phase detector.
